(19) United States
(12) Patent Application Publication
(10) Pub. No.: US 2024/0295743 A1
(43) Pub. Date: Sep. 5, 2024

(54) SYSTEM AND METHOD FOR IMAGING USING SPECKLE-FREE ILLUMINATION

(71) Applicant: Orbotech Ltd., Yavne (IL)

(72) Inventor: Jonathan Azogui, Beer Sheva (IL)

(21) Appl. No.: 18/582,408

(22) Filed: Feb. 20, 2024

Related U.S. Application Data
(60) Provisional application No. 63/449,319, filed on Mar. 2, 2023.

(51) Int. Cl. G02B 27/48; H01S 3/06; H01S 3/16

(52) U.S. Cl. CPC G02B 27/48; H01S 3/0619; H01S 3/169

(57) ABSTRACT

An illumination system comprising is disclosed. The illumination system may include a narrowband illumination source. The illumination system may include an illumination path including one or more illumination optics. The illumination system may include a quantum dot assembly within the illumination path, the quantum dot assembly comprising a quantum dot layer disposed on a substrate, wherein the quantum dot assembly is configured to receive a narrowband illumination beam from the narrowband illumination source and emit a converted illumination beam having a spectral range broader than the narrowband illumination beam. The illumination system may include wherein the one or more illumination optics are configured to direct illumination from the quantum dot assembly to a sample disposed on a sample stage.

### CROSS-REFERENCE TO RELATED APPLICATION

The present application claims the benefit under 35 U.S.C. § 119(e) of U.S. Provisional Application Ser. No. 63/449,319, filed Mar. 2, 2023, which is incorporated herein by reference in the entirety.

### TECHNICAL FIELD

The present disclosure relates to high-brightness laser illumination, and, more particularly, to the use of high brightness laser illumination free of speckle noise for use in imaging systems illumination systems.

### BACKGROUND

Imaging and metrology systems use illumination to image sample surfaces. Commonly, the illumination used in the imaging of samples, such as semiconductor wafers, is generated from one or more laser sources. However, laser illumination is often susceptible to speckle noise caused by the interference of the coherent light. The presence of speckle noise makes it difficult or impossible to obtain accurate images and/or measurements of a given sample. Obtaining speckle-free illumination is critical for imaging purposes. Current methods for generating speckle-free illumination include the use of a multi-diode array, polarization multiplexing methods, and time multiplexing methods. Each of these current approaches have drawbacks. Multi-diode arrays require very large arrays of diodes, polarization multiplexing is not always feasible, and time multiplexing methods are not suitable for short pulses of illumination. Therefore, there is a desire to cure the shortcomings of prior approaches to mitigate the presence of speckle in inspection and/or metrology systems.

### SUMMARY

An illumination system is disclosed. In embodiments, the illumination system includes a narrowband illumination source. In embodiments, the illumination system includes an illumination path including one or more illumination optics. In embodiments, the illumination system includes a quantum dot assembly positioned within the illumination path, the quantum dot assembly comprising a quantum dot layer disposed on a substrate, wherein the quantum dot assembly is configured to receive a narrowband illumination beam from the narrowband illumination source and emit a converted illumination beam having a spectral range broader than the narrowband illumination beam. In embodiments, the illumination system includes wherein the one or more illumination optics are configured to direct illumination from the quantum dot assembly to a sample disposed on a sample stage.

An optical characterization system is disclosed. In embodiments, the characterization system includes an illumination sub-system. In embodiments, the illumination sub-system includes a narrowband illumination source. In embodiments, the illumination sub-system includes an illumination path including one or more illumination optics. In embodiments, the characterization system includes a quantum dot assembly positioned within the illumination path, the quantum dot assembly comprising a quantum dot layer disposed on a substrate, wherein the quantum dot assembly is configured to receive a narrowband illumination beam from the narrowband illumination source and emit a converted illumination beam having a spectral range broader than the narrowband illumination beam. In embodiments, the one or more illumination optics are configured to direct illumination from the quantum dot assembly to a sample disposed on a sample stage. In embodiments, the characterization system includes a detector. In embodiments, the characterization system includes a collection sub-system configured to collect illumination from the same and project the illumination onto the detector.

A method is disclosed. In embodiments, the method includes a step of generating a narrowband illumination beam. In embodiments, the method includes a step of directing the narrowband illumination beam along an illumination path including one or more illumination optics. In embodiments, the method includes a step of converting the narrowband illumination beam to a converted illumination beam with a quantum dot assembly positioned within the illumination path, wherein the quantum dot assembly includes a quantum dot layer disposed on a substrate. In embodiments, the method includes a step of directing the converted illumination beam from the quantum dot assembly to a sample disposed on a sample stage. In embodiments, the method includes a step of projecting illumination from the sample onto a detector.

### BRIEF DESCRIPTION OF THE DRAWINGS

The numerous advantages of the disclosure may be better understood by those skilled in the art by reference to the accompanying figures.

FIG. 1A illustrates a simplified schematic view of an illumination system with a quantum dot assembly disposed between two sets of illumination optics, in accordance with one or more embodiments of the present disclosure.

FIG. 1B illustrates a conceptual view of a quantum dot assembly, in accordance with one or more embodiments of the present disclosure.

FIG. 1C illustrates a conceptual view of the quantum dot assembly including a dichroic coating deposited on a front surface of the substrate, in accordance with one or more embodiments of the present disclosure.

FIG. 1D illustrates a conceptual view of the quantum dot assembly including a dichroic coating deposited on a back surface of the substrate, in accordance with one or more embodiments of the present disclosure.

FIG. 2 illustrates a simplified schematic view of the illumination system with the quantum dot assembly disposed at the output of a narrowband illumination source, in accordance with one or more embodiments of the present disclosure.

FIG. 3 illustrates a simplified schematic view of the illumination system with a reflective quantum dot assembly, in accordance with one or more embodiments of the present disclosure.

FIG. 4A illustrates a block diagram view of an optical characterization system incorporating the quantum-dot-based illumination system, in accordance with one or more embodiments of the present disclosure.

FIG. 4B illustrates a block diagram view of a brightfield optical characterization system incorporating the quantum-dot-based illumination system, in accordance with one or more embodiments of the present disclosure.

FIG. 4C illustrates a block diagram view of a transmission-based optical characterization system incorporating the quantum-dot-based illumination system, in accordance with one or more embodiments of the present disclosure.

FIG. 5 illustrates a flow diagram depicting a method of generating speckle-free high-brightness illumination, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

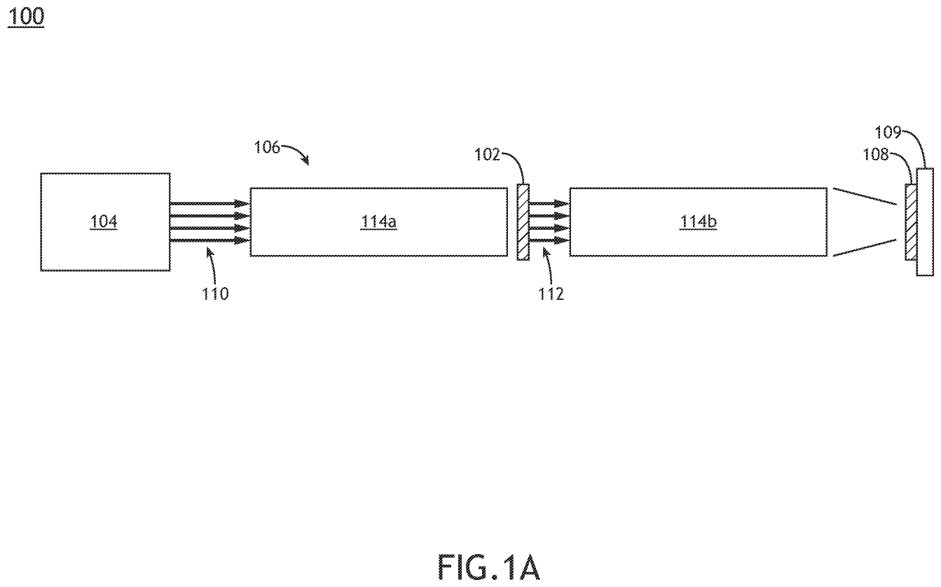

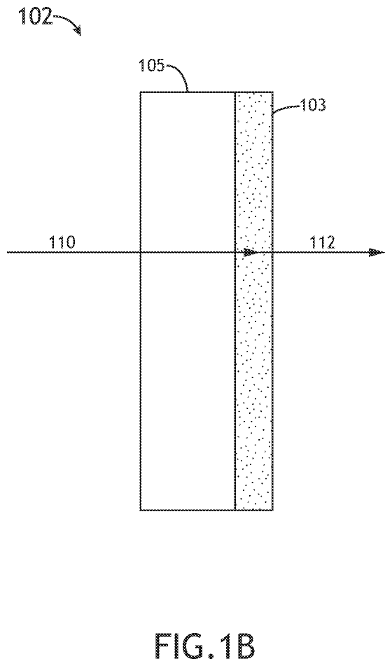

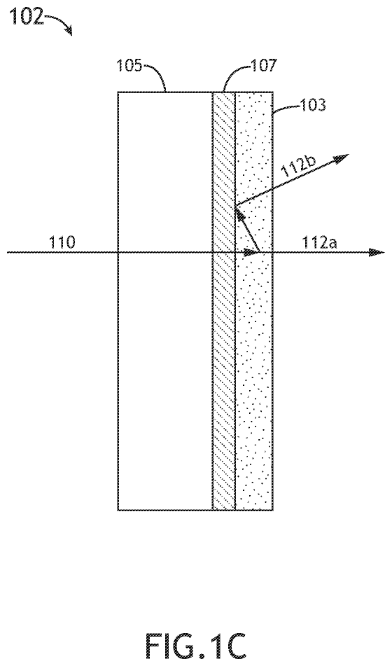

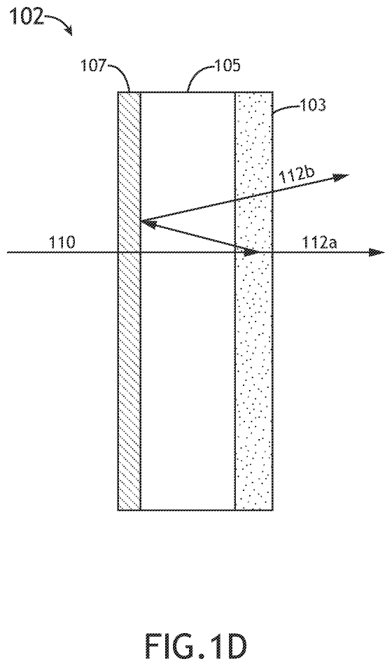

FIGS. 1A-3 illustrate an illumination system equipped with a quantum dot assembly to broaden narrowband illumination to prevent the generation of speckle-noise within an optical system. Embodiments of the present disclosure are directed to the elimination of speckle within a narrow-band (e.g., laser) illumination system using a quantum dot array. For example, within an illumination system of an optical characterization system (e.g., inspection system or imaging-based metrology system), it may be advantageous to position a quantum dot array within the illumination arm of the optical characterization system and between the narrowband illumination source and a sample.

Embodiments of the present disclosure implement quantum dots to perform color conversion of laser illumination from an illumination source in a manner that broadens the spectrum of the illumination. As a result of the spectral broadening of the imaging illumination, the presence of speckle-noise may be reduced or eliminated within the optical system.

FIGS. 1A-1B illustrate an illumination system 100 for broadening narrowband illumination, in accordance with one or more embodiments of the present disclosure. In embodiments, the illumination system 100 includes a quantum dot assembly 102 configured for broadening the spectral range of incident illumination 110 from a narrowband illumination source 104 (e.g., a laser source).

As shown in FIG. 1B, the quantum dot assembly 102 may include a quantum dot layer 103 disposed on a substrate 105. The quantum dot assembly 102 may be positioned within an illumination path 106 of the illumination system 100. The quantum dot layer 103 may be disposed on any type of substrate 105. For example, the quantum dot layer 103 may be disposed on a transparent substrate. In this case, the transparent quantum dot assembly 102 may be utilized in settings which require transmission through the quantum dot assembly 102. A transparent substrate 105 may include, but is not limited to, glass. By way of another example, the quantum dot layer 103 may be disposed on a reflective substrate. In this case, the reflective quantum dot assembly 102 may be utilized in settings which require reflection from the quantum dot assembly 102. A reflective substrate 105 may include, but is not limited to, a mirror.

As shown in FIGS. 1C-1D, in embodiments, one or more surfaces of the transparent substrate 105 may be coated with a dichroic coating 107. The dichroic coating 107 may allow the narrowband illumination 110 from the illumination source 104 to pass through the substrate 105 but reflects other wavelengths of illumination. For example, the dichroic coating 107 may be selected such that it is transparent to the narrowband illumination 110 from the illumination source 104 but reflective of the converted illumination 112. The dichroic coating 107 may back reflect any converted illumination 112b emitted by the quantum dot layer 102 traveling back toward the narrowband source 104 to redirect that illumination to the sample 108. Converted illumination 112a that is emitted in the desired direction continues unobstructed. The dichroic coating 107 will decrease the amount of lost illumination and increase efficiency of the illumination system 100. For example, as shown in FIG. 1C, a dichroic coating 107 may be deposited on a front surface of the substrate 105 prior to deposition of the quantum dot layer 103. By way of another example, as shown in FIG. 1D, the dichroic coating 107 may be deposited on a back surface of the substrate 105. The quantum dot layer 103 may be formed by dispersing a selected amount of quantum dots within a polymer medium and coating the substrate/dichroic coating structure with the polymer medium. For example, the selected amount of quantum dots may be dissolved in a solution and solidified in a polymer layer on the substrate/dichroic coating structure.

The quantum dot assembly 102 may act as a passive element within a system the illumination system 100 to modify an incident illumination beam 110. The quantum dot assembly 102 may simultaneously convert incident light to a desired central wavelength and broaden the spectrum of the light. The utilization of the broadened spectrum may eliminate or reduce speckle noise within the optical.

The narrowband illumination source 104 may include any light source capable of producing a narrowband illumination beam 110. For example, the narrowband illumination source 104 may include, but is not limited to, one or more lasers. For instance, the one or more lasers may include one or more continuous wave (CW) lasers and/or one or more pulsed lasers.

In embodiments, the quantum dot assembly 102 may be positioned downstream from the narrowband illumination source 104. In this way, the quantum dot assembly 102 may be configured to receive the narrowband illumination beam 110. After receiving the narrowband illumination beam 110, the quantum dot assembly 102 may convert the narrowband illumination beam 110 to a converted illumination beam 112. The converted illumination beam 112 may have a spectral range that is broader than the initial narrowband illumination beam 110 as well as shifted relative to the initial narrowband illumination. It is noted herein that the converted illumination beam 112 may have spectral characteristics similar to a light emitting diode (LED). The converted illumination beam 112 may include any number of wavelengths of light (e.g., red, green, blue). It is noted that the color of the converted illumination beam 112 may be dependent on the type of quantum dot assembly 102 used in the illumination system 100 and the spectral content of the initial illumination beam 110. For example, the quantum dot assembly 102 may convert an incident blue laser beam to a royal blue-green laser beam or a red laser beam having a spectral range broader than the initial beam. By way of another example, the quantum dot assembly 102 may convert an incident green laser to a longer wavelength green laser beam or a red laser beam having a spectral range broader than the initial beam. By way of another example, the quantum dot assembly 102 may convert an incident red (or amber) laser beam to a longer wavelength red laser having a spectral range broader than the initial beam. It should be understood that the examples of color conversion are provided merely for illustrative purposes and should not be interpreted as limiting on the scope of the present disclosure.

In embodiments, the illumination system 100 includes an illumination path 106 with one or more illumination optics 114a, 114b. In embodiments, the illumination optics 114a, 114b may direct the narrowband illumination beam 110 from the narrowband illumination source 104 to the quantum dot assembly 102 and direct the converted illumination beam 112 from the quantum dot assembly 102 to the sample 108 disposed on a sample stage 109. The illumination optics 114a, 114b may include, but are not limited to, projection optics or homogenizer optics.

In embodiments, as shown in FIG. 1A, the quantum dot assembly 102 may be positioned between two or more illumination optics 114a, 114b in a transmission configuration. For example, such a configuration may be accomplished using a quantum dot assembly 102 that is at least partially transparent. For example, the quantum dot layer 103 of the quantum dot assembly 102 may be disposed on a transparent glass substrate 105.

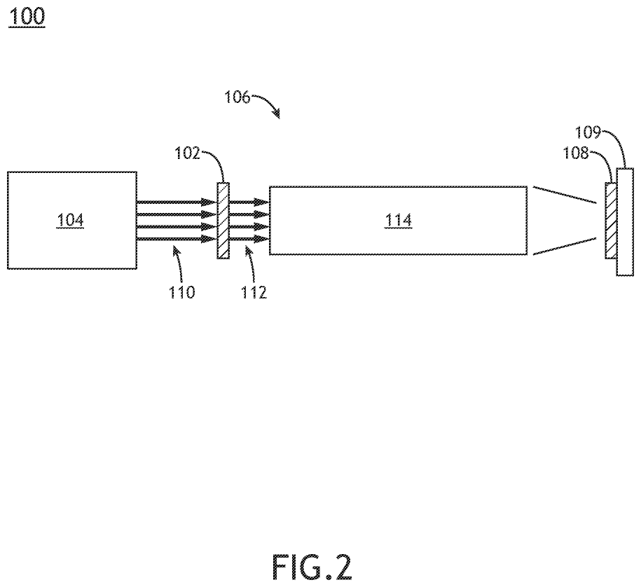

FIG. 2 illustrates the quantum dot assembly 102 disposed at the output of the narrowband illumination source 104. For example, the quantum dot assembly 102 may be transparent and positioned between the narrowband illumination source 104 and the illumination optic 114.

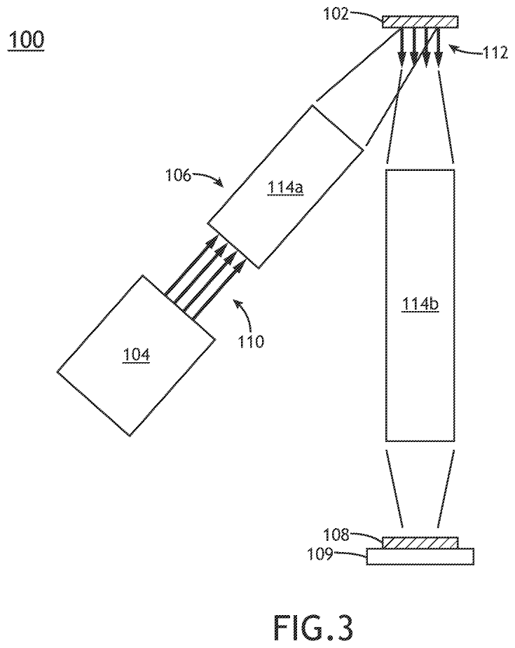

FIG. 3 illustrates the illumination system with a reflective quantum dot assembly 102, in accordance with one or more embodiments of the present disclosure. In embodiments, the illumination optics 114a, 114b may be located at an angle to one another in a reflection configuration between a first illumination optic 114a and a second illumination optic 114b. For example, such a configuration may be accomplished using a quantum dot assembly 102 that is at least partially reflective. For instance, the quantum dot layer 103 of the quantum dot assembly 102 may be disposed on a reflective substrate 105.

It is noted that the examples depicted in FIG. 1A-3 should not be interpreted as a limitation on the scope of the present disclosure and are provided merely for illustrative purposes. Rather, it should be understood that the location of the quantum dot assembly 102 may vary significantly and may be positioned relative to the other components of the illumination system in any number of ways. As a nonlimiting example, the quantum dot assembly 102 may be located near the narrowband illumination source 104 and/or after some illumination optics 114a, 114b. The location of the quantum dot assembly 102 may be dictated by design considerations for the illumination system 100 For example, the quantum dot assembly 102 may be located after a single illumination optic.

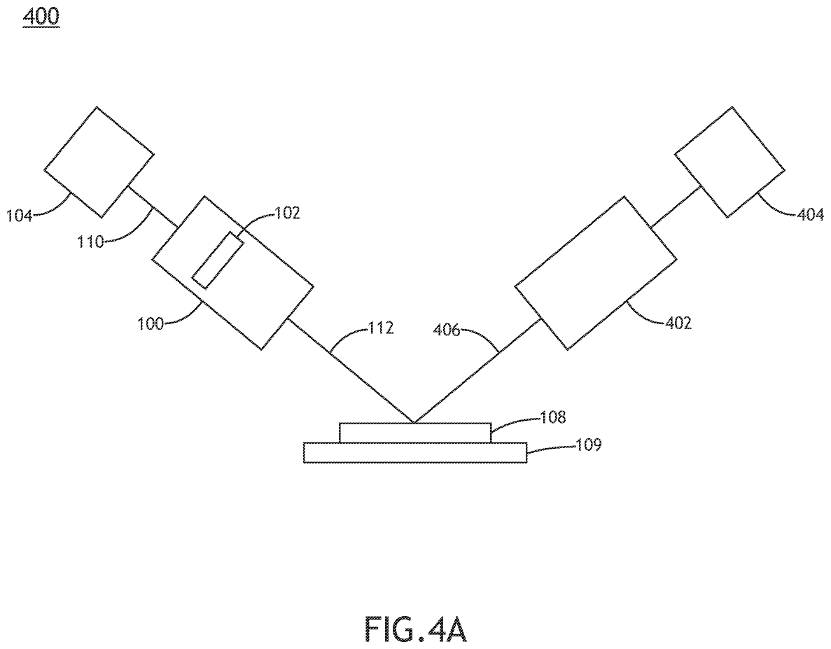

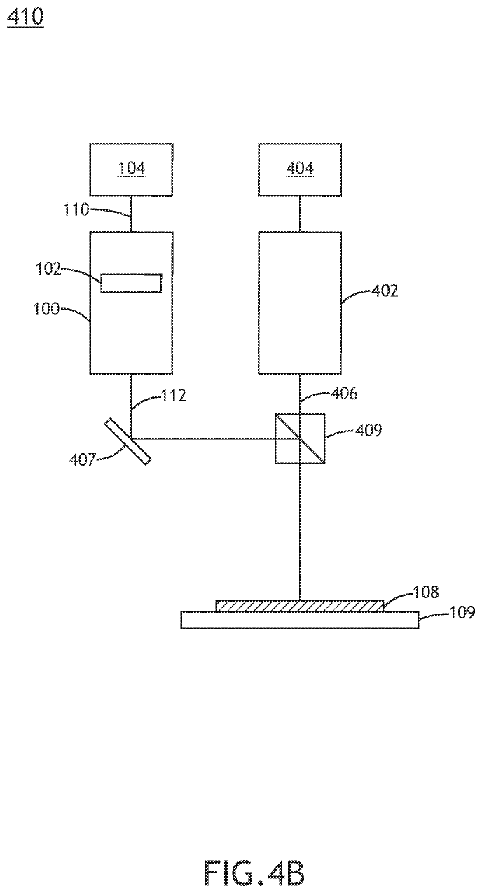

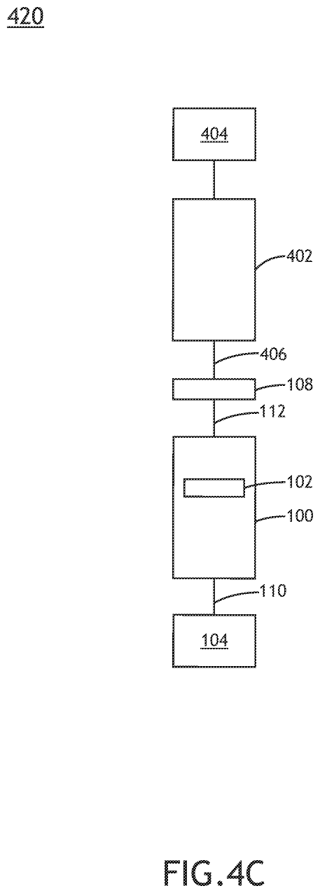

FIGS. 4A-4C illustrate a variety of optical characterization system configurations incorporating the illumination system 100 of the present disclosure. It is noted that the illustrations of FIGS. 4A-4C are provided merely for illustrative purposes and should not be interpreted as a limitation on the scope of the present disclosure.

FIG. 4A illustrates a block diagram depicting an optical characterization system 400 incorporating the illumination system 100, in accordance with one or more embodiments of the present disclosure. In embodiments, the optical characterization system 400 includes the illumination sub-system 100 equipped with the quantum dot assembly 102. The illumination sub-system 100 should be interpreted to include all of the implementations and features discussed with reference to the illumination system 100 of FIGS. 1-3.

In embodiments, the optical characterization system 400 may include a collection sub-system 402 and a detector 404. The collection sub-system 402 may collect illumination 406 from the sample 108 and project that illumination 406 onto the detector 404. For example, such collected illumination 406 may be used for inspection and/or metrology of the sample 108. It is noted that the conversion of the narrowband illumination beam 110 to the converted illumination beam 112 may reduce speckle noise at the detector 404 due to the broader spectral range of the converted illumination beam 112 relative to the input beam 110 which reduces the presence of interference artifacts within the system 400.

FIG. 4B illustrates a block diagram depicting an optical characterization system 420 in a brightfield configuration incorporating the illumination system 100, in accordance with one or more embodiments of the present disclosure. In embodiments, the optical characterization system 410 includes the illumination sub-system 100 equipped with the quantum dot assembly 102. The illumination sub-system 100 should be interpreted to include all of the implementations and features discussed with reference to the illumination system 100 of FIGS. 1-4A. In embodiments, the optical characterization system 410 includes a mirror 407 and a beamsplitter 409 to couple the converted illumination beam 112 to the sample 108. In this regard, the mirror 407 directs converted illumination 112 to the beamsplitter 409. In turn, the beamsplitter 409 directs the converted illumination 112 to the sample 108. In additional and/or alternative embodiments, the quantum dot assembly 102 may be integrated within the mirror 407. The beamsplitter 409 may transmit illumination from the sample 108 along the collection pathway to the collection sub-system 402 and the detector 404. The collection sub-system 402 may collect illumination 406 from the sample 108 and project that illumination 406 onto the detector 404. For example, such collected illumination 406 may be used for inspection and/or metrology of the sample 108.

FIG. 4C illustrates a block diagram depicting an optical characterization system 420 in a transmission configuration incorporating the illumination system 100, in accordance with one or more embodiments of the present disclosure. In embodiments, the optical characterization system 420 includes the illumination sub-system 100 equipped with the quantum dot assembly 102. The illumination sub-system 100 should be interpreted to include all of the implementations and features discussed with reference to the illumination system 100 of FIGS. 1-4B. In embodiments, the illumination source 104 and the illumination sub-system 100 are positioned on a side of the sample 108 (e.g., below the sample) opposite of the collection sub-system 402 and detector 404 (e.g., above the sample). In this regard, converted illumination 112 is transmitted through the sample 108. In turn, the collection sub-system 402 may collect illumination 406 that is transmitted through the sample 108 and project that illumination 406 onto the detector 404.

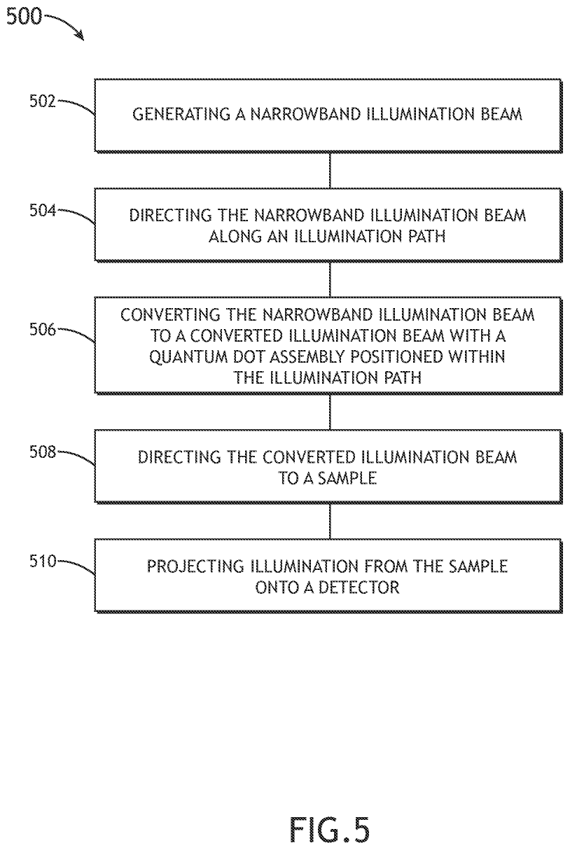

FIG. 5 illustrates a flow diagram depicting a method 500 for speckle-free high brightness illumination, in accordance with one or more embodiments of the present disclosure. Applicant notes that the implementations and enabling technologies described previously herein in the context of the illumination system 100 and/or the characterization system 400 should be interpreted to extend to the method 500. It is further noted, however, that the method 500 is not limited to the architecture of the illumination system 100 and/or the narrowband characterization system 400.

In embodiments, the method 500 includes a step 502 of generating a narrowband illumination beam. For example, the narrowband illumination beam may be generated by one or more narrowband illumination sources. The narrowband illumination source may include one or more lasers.

In embodiments, the method 500 includes a step 504 of directing the narrowband illumination beam along an illumination path including one or more illumination optics. The one or more illumination optics may include one or more projection optics or homogenizer optics.

In embodiments, the method 500 includes a step 506 of converting the narrowband illumination beam to a converted illumination beam with a quantum dot assembly positioned within the illumination path, wherein the quantum dot assembly includes a quantum dot layer disposed on a substrate. The converted illumination beam may have a broader spectral range than the input narrowband illumination beam. The broader spectral range may reduce spectral noise at a detector. The converted illumination beam may include at least one of red light, green light, or blue light.

In embodiments, the method 500 includes a step 508 of directing the converted illumination beam from the quantum dot assembly to a sample disposed on a sample stage. For example, the converted illumination beam may be (but need not be) directed to the sample with one or more illumination optics.

In embodiments, the method 500 includes a step 510 of projecting illumination from the sample onto a detector. This may allow for inspection or metrology on the sample.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed is:

1. An illumination system comprising:
a narrowband illumination source;
an illumination path including one or more illumination optics; and
a quantum dot assembly positioned within the illumination path, the quantum dot assembly comprising a quantum dot layer disposed on a substrate, wherein the quantum dot assembly is configured to receive a narrowband illumination beam from the narrowband illumination source and emit a converted illumination beam having a broader spectral range than the narrowband illumination beam,
wherein the one or more illumination optics are configured to direct illumination from the quantum dot assembly to a sample disposed on a sample stage.

2. The illumination system of claim 1, wherein the broader spectral range of the converted illumination beam reduces speckle noise at a detector.

3. The illumination system of claim 1, wherein the narrowband illumination source comprises one or more lasers.

4. The illumination system of claim 1, wherein the quantum dot layer is disposed on a transparent substrate.

5. The illumination system of claim 4, further comprising a dichroic coating deposited on a surface of the transparent substrate.

6. The illumination system of claim 1, wherein the quantum dot layer is disposed on a reflective substrate.

7. The illumination system of claim 1, wherein the quantum dot assembly is transparent and positioned between two or more illumination optics.

8. The illumination system of claim 7, wherein the two or more illumination optics comprise two or more projection optics or homogenizer optics.

9. The illumination system of claim 1, wherein the quantum dot assembly is transparent and positioned between the narrowband illumination source and the one or more illumination optics.

10. The illumination system of claim 1, wherein the quantum dot assembly is reflective and positioned between a first illumination optic and a second illumination optic.

11. The illumination system of claim 1, wherein the illumination system is integrated within at least one of an inspection system or a metrology system.

12. An optical characterization system comprising:
an illumination sub-system comprising:
a narrowband illumination source;
an illumination path including one or more illumination optics; and
a quantum dot assembly positioned within the illumination path, the quantum dot assembly comprising a quantum dot layer disposed on a substrate, wherein the quantum dot assembly is configured to receive a narrowband illumination beam from the narrowband illumination source and emit a converted illumination beam having a spectral range broader than the narrowband illumination beam;
wherein the one or more illumination optics are configured to direct illumination from the quantum dot assembly to a sample disposed on a sample stage;
a detector; and
a collection sub-system configured to collect illumination from the sample and project the illumination onto the detector.

13. The optical characterization system of claim 12, wherein the broader spectral range of the converted illumination beam reduces speckle noise at the detector.

14. The optical characterization system of claim 12, wherein the narrowband illumination source comprises one or more lasers.

15. The optical characterization system of claim 12, wherein the quantum dot layer is disposed on a transparent substrate.

16. The optical characterization system of claim 15, further comprising a dichroic coating deposited on a surface of the transparent substrate.

17. The optical characterization system of claim 12, wherein the quantum dot layer is disposed on a reflective substrate.

18. The optical characterization system of claim 12, wherein the quantum dot assembly is transparent and positioned between two or more illumination optics.

19. The optical characterization system of claim 12, wherein the quantum dot assembly is transparent and positioned between the narrowband illumination source and the one or more illumination optics.

20. The optical characterization system of claim 12, wherein the quantum dot assembly is reflective and positioned between two or more illumination optics.

21. The optical characterization system of claim 12, wherein the optical characterization system is configured as an inspection system or a metrology system.

22. A method comprising:
generating a narrowband illumination beam;
directing the narrowband illumination beam along an illumination path including one or more illumination optics;
converting the narrowband illumination beam to a converted illumination beam with a quantum dot assembly positioned within the illumination path, wherein the quantum dot assembly includes a quantum dot layer disposed on a substrate;
directing the converted illumination beam from the quantum dot assembly to a sample disposed on a sample stage; and
projecting illumination from the sample onto a detector.
